(19) United States
(12) Patent Application Publication
(10) Pub. No.: US 2025/0380616 A1
(43) Pub. Date: Dec. 11, 2025

(54) STT MRAM DEVICE WITH PERPENDICULAR EXCHANGE BIAS LAYER IN CONTACT WITH FREE LAYER

(71) Applicant: SANDISK TECHNOLOGIES LLC, ADDISON, TX (US)

(72) Inventors: Goran MIHAJLOVIC, San Jose, CA (US); Wonjoon JUNG, San Jose, CA (US)

(21) Appl. No.: 18/781,035

(22) Filed: Jul. 23, 2024

Related U.S. Application Data
(60) Provisional application No. 63/656,479, filed on Jun. 5, 2024.

(51) Int. Cl. H10N 50/20; H10B 61/00; H10N 50/10; H10N 50/85

(52) U.S. Cl. CPC H10N 50/20; H10B 61/10; H10N 50/10; H10N 50/85

(57) ABSTRACT

A spin transfer torque (STT) magnetoresistive memory cell includes a magnetic tunnel junction including a reference layer, a free layer, and a nonmagnetic tunnel barrier located between the reference layer and the free layer, and perpendicular exchange bias layer in contact with the free layer.

### FIELD

The present disclosure relates generally to the field of magnetic memory devices and specifically to a spin-transfer torque magnetoresistive random access memory device with perpendicular exchange bias layer contacting the free layer.

### BACKGROUND

Spin-transfer torque (STT) refers to an effect in which the orientation of a magnetic layer in a magnetic tunnel junction or spin valve is modified by a spin-polarized current. Generally, electric current is unpolarized with electrons having random spin orientations. A spin polarized current is one in which electrons have a net non-zero spin due to a preferential spin orientation distribution. A spin-polarized current can be generated by passing electrical current through a magnetic polarizer layer. When the spin-polarized current flows through a ferromagnetic free layer of a magnetic tunnel junction or a spin valve, the electrons in the spin-polarized current can transfer at least some of their angular momentum to the free layer, thereby producing a torque on the magnetization of the free layer. When a sufficient amount of spin-polarized current passes through the free layer, spin-transfer torque can be employed to flip the orientation of the spin (e.g., change the magnetization) in the free layer. A resistance differential of a magnetic tunnel junction between different magnetization states of the free layer can be employed to store data within the magnetoresistive random access memory (MRAM) cell depending if the magnetization of the free layer is parallel or antiparallel to the magnetization of the ferromagnetic reference layer.

### SUMMARY

According to an aspect of the present disclosure, a spin transfer torque (STT) magnetoresistive memory cell comprises a magnetic tunnel junction comprising a reference layer, a free layer, and a nonmagnetic tunnel barrier layer located between the reference layer and the free layer; and a perpendicular exchange bias layer in direct contact with a planar surface of the free layer.

### BRIEF DESCRIPTION OF THE DRAWINGS

FIG. 1 is a schematic diagram of a memory device including an array of magnetoresistive memory cells according to an embodiment of the present disclosure.

FIG. 2A illustrates a schematic view of an exemplary spin-transfer torque MRAM cell including a perpendicular exchange bias layer according to an embodiment of the present disclosure.

FIG. 2B illustrates a schematic view of an exemplary spin-transfer torque MRAM cell including a perpendicular exchange bias layer and a selector element according to an embodiment of the present disclosure.

FIG. 3A is a schematic illustration of a parallel-to-antiparallel programming operation on the STT MRAM cell according to an embodiment of the present disclosure.

FIG. 3B is a schematic illustration of an antiparallel-to-parallel programming operation on the STT MRAM cell of the present disclosure according to an embodiment of the present disclosure.

### DETAILED DESCRIPTION

As discussed above, the present disclosure is directed to a spin-transfer torque MRAM device with enhanced magnetic immunity in which a perpendicular exchange bias layer contacts the free layer, and methods of operating the same, the various aspects of which are described below.

The drawings are not drawn to scale. Multiple instances of an element may be duplicated where a single instance of the element is illustrated, unless absence of duplication of elements is expressly described or clearly indicated otherwise. Same reference numerals refer to the same element or a similar element. Elements having the same reference numerals are presumed to have the same material composition unless expressly stated otherwise. Ordinals such as 'first," "second", and "third" are employed merely to identify similar elements, and different ordinals may be employed across the specification and the claims of the instant disclosure. As used herein, an element located "on" a second element can be located on the exterior side of a surface of the second element or on the interior side of the second element. As used herein, an element is located "directly on" a second element if there exist a physical contact between a surface of an element and a surface of the second element. As used herein, an "in-process" structure or a "transient" structure refers to a structure that is subsequently modified.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, and/or may have one or more layer thereupon, thereabove, and/or therebelow.

As used herein, a “layer stack” refers to a stack of layers. As used herein, a “line” refers to a layer that has a predominant direction of extension, i.e., having a direction along which the layer extends the most.

The magnetization orientation of the free layer in prior art STT MRAM devices is sensitive to external magnetic fields, which can flip the magnetization direction of the free layer and erase stored data. The free layer, which is the data storage layer, is sandwiched between two M_{g}O layers in prior art STT MRAM devices, and has weaker perpendicular magnetic anisotropy (PMA) energy than the magnetic polarizer layer and the reference layer. The free layer has uniaxial anisotropy, meaning it has two stable energy minima, and a strong enough external magnetic field can switch the magnetization between these minima, potentially erasing data bit. Thus, if the external magnetic field is sufficiently large, the magnetization orientation of the free layer, can be flipped, and the data stored in the form of the magnetization direction of the free layer can be lost.

Embodiments of the present disclosure provide a perpendicular exchange bias layer in contact with the free layer of a STT MRAM cell. The perpendicular exchange bias layer replaces the capping MgO layer which is in contact with the free layer in prior art STT MRAM cells. The perpendicular exchange bias layer can be switched by the spin-transfer torque (STT), but not by an external magnetic field. In other words, the perpendicular exchange bias layer provides unidirectional anisotropy with respect to the external magnetic field, and thus magnetic field immunity, but still acts as an uniaxial anisotropy layer when it comes to STT.

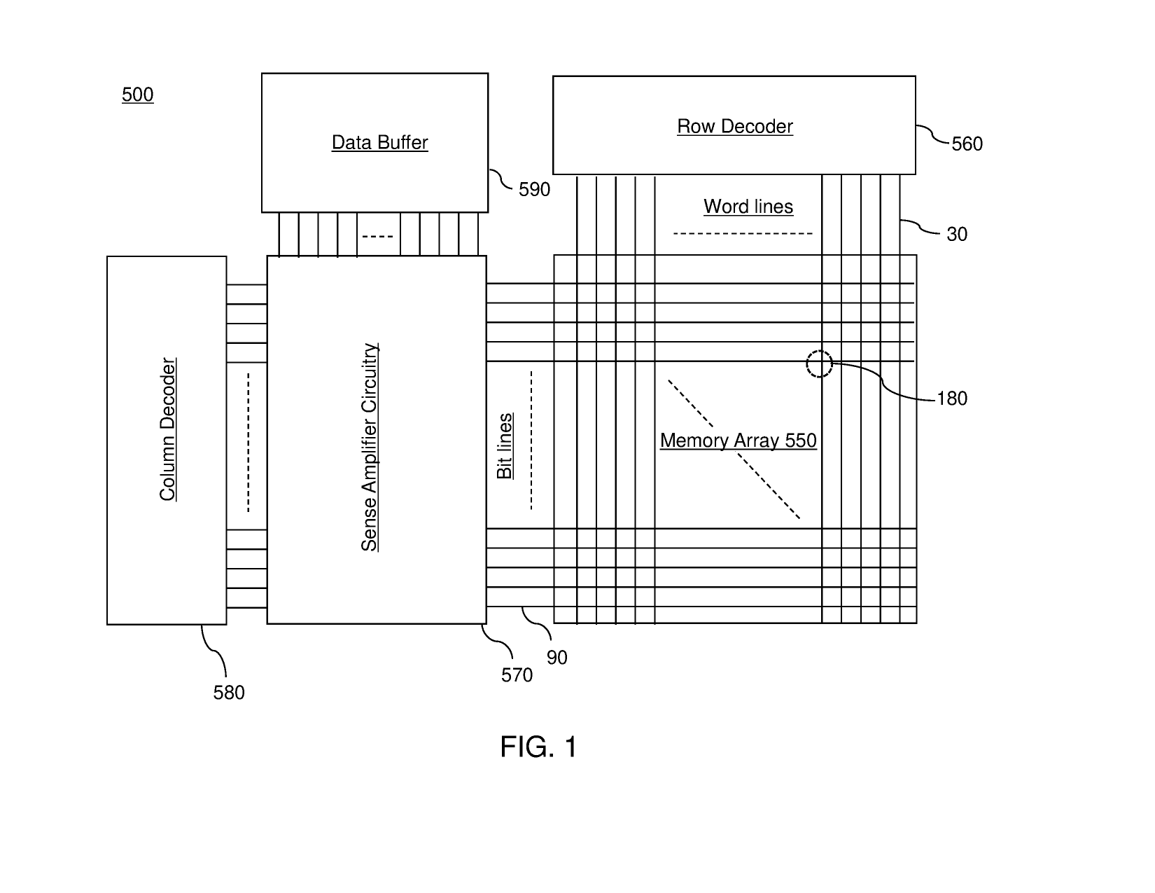

Referring to FIG. 1, a schematic diagram is shown for a magnetoresistive random access memory (RAM) device 500 including memory cells 180 of any embodiment of the present disclosure in an array configuration. The RAM device 500 includes an array of memory cells 180, which may be configured as a two-dimensional array or as a three-dimensional array. As used herein, a “random access memory” (RAM) refers to a memory device containing memory cells that allow random access, e.g., access to any selected memory cell upon a command for reading the contents of the selected memory cell. The RAM device 500 of the embodiment of the present disclosure is a random access memory device including a magnetoresistive memory element within each memory cell.

The RAM device 500 of an embodiment of the present disclosure includes a memory array region 550 containing an array of memory cells 180 located at the intersection of the respective word lines (which may comprise the first electrically conductive lines 30 as illustrated, or may comprise the second electrically conductive lines 90 in an alternate configuration) and bit lines (which may comprise the second electrically conductive lines 90 as illustrated, or may comprise the first electrically conductive lines 30 in an alternate configuration). Each of the magnetoresistive memory cells 180 can be a two-terminal memory cell including a respective first electrode and a respective second electrode. In one embodiment, the first electrodes can be connected to the first electrically conductive lines 30, and the second electrodes can be connected to the second electrically conductive lines 90. Alternatively, the first electrodes can be connected to the second electrically conductive lines 90, and the second electrodes can be connected to the first electrically conductive lines 30.

The RAM device 500 may also contain a row decoder 560 connected to the word lines, a sense circuitry 570 (e.g., a sense amplifier and other bit line control circuitry) connected to the bit lines, a column decoder 580 connected to the bit lines, and a data buffer 590 connected to the sense circuitry. Multiple instances of the magnetoresistive memory cells 180 are provided in an array configuration that forms the RAM device 500. It should be noted that the location and interconnection of elements are schematic and the elements may be arranged in a different configuration. Further, a magnetoresistive memory cell 180 may be manufactured as a discrete device, i.e., a single isolated device.

Each memory cell 180 includes a magnetic tunnel junction having at least two different resistive states depending on the alignment of magnetizations of different magnetic material layers. The magnetic tunnel junction is provided between an electrode and a second electrode within each memory cell 180. In one embodiment, the RAM device 500 comprises a spin-transfer torque (STT) magnetic random access memory (MRAM) device, and each memory cell 180 can be a spin-transfer torque magnetic tunnel junction memory cell. The magnetization of the free layer can be programmed deterministically by bidirectional spin-polarized current that tunnels through a magnetic tunnel junction.

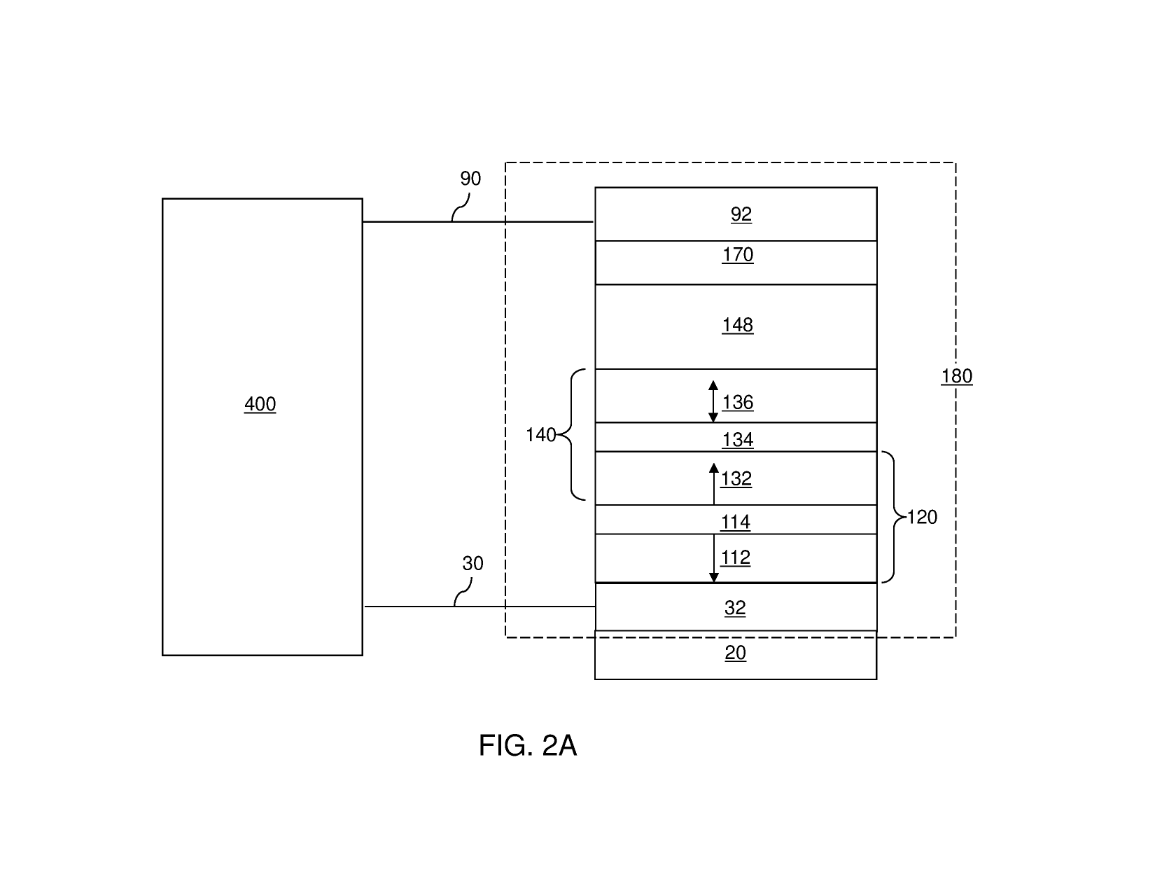

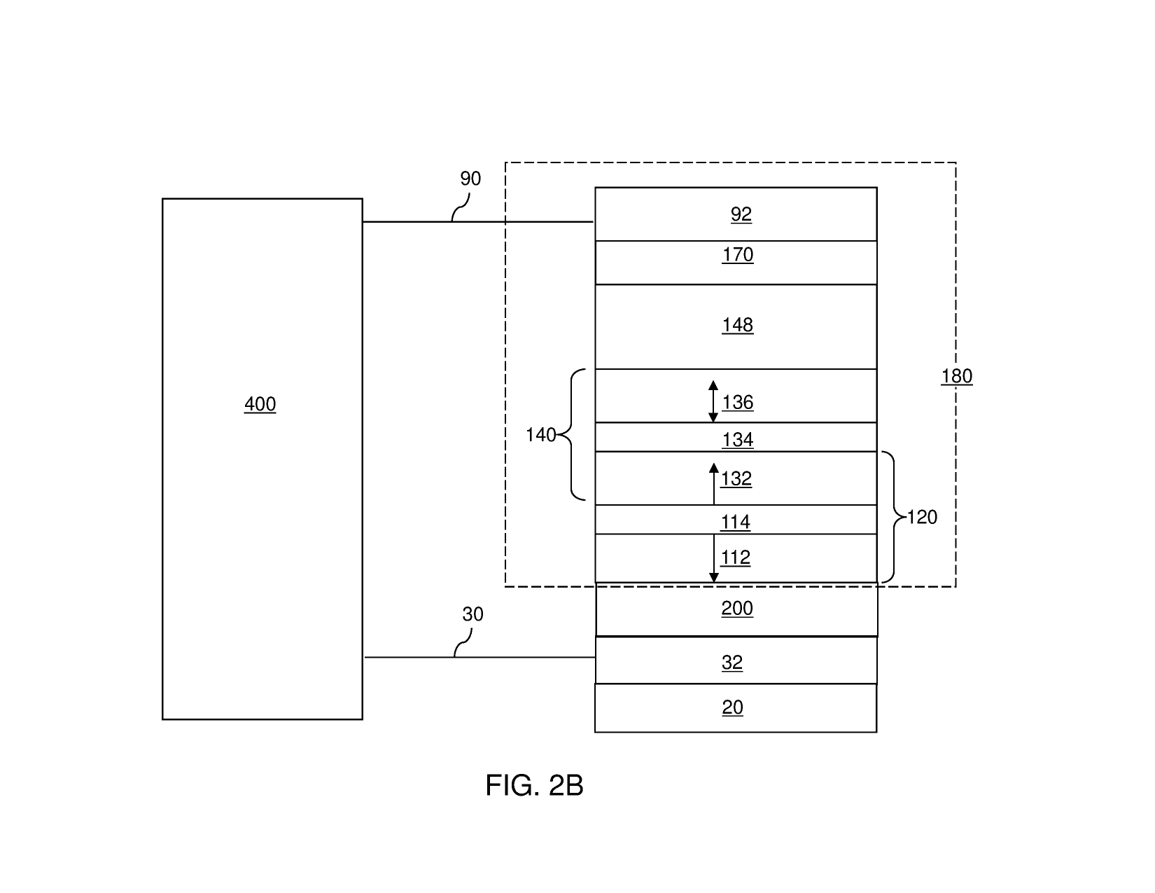

Referring to FIG. 2A, an exemplary magnetoresistive memory device according to an embodiment of the present disclosure is illustrated, which comprises a magnetoresistive memory cell 180. The magnetoresistive memory cell 180 may be employed within the STT MRAM device 500 illustrated in FIG. 1. According to the embodiment of the present disclosure, the magnetoresistive memory cell 180 may be a spin-transfer torque magnetic tunnel junction memory cell. The magnetoresistive memory cell 180 can be formed on an insulating support 20 (which may include a silicon oxide layer), and can include a first electrode 32 that may be electrically connected to or comprises a portion of a first electrically conductive line 30 (such as a word line or a bit line) and a second electrode 92 that may be electrically connected to, or comprises, a portion of a second electrically conductive line 90 (such as a bit line or a word line).

The magnetoresistive memory cell 180 includes a magnetic tunnel junction (MTJ) 140. The magnetic tunnel junction 140 includes a ferromagnetic reference layer 132 (which may also be referred to as a “pinned” layer) having a fixed vertical magnetization, a nonmagnetic tunnel barrier layer 134, and the ferromagnetic free layer 136 (which may also be referred to as a “storage” layer) having a magnetization direction that can be programmed. The reference layer 132 and the free layer 136 are separated by the nonmagnetic tunnel barrier layer 134 (such as an MgO layer), and have a magnetization direction perpendicular to the interface between the free layer 136 and the nonmagnetic tunnel barrier layer 134.

In one embodiment, the reference layer 132 is located below the nonmagnetic tunnel barrier layer 134, while the free layer 136 is located above the nonmagnetic tunnel barrier layer 134. A perpendicular exchange bias layer 148 may be formed on top of the free layer 136. However, in other embodiments, the reference layer 132 is located above the nonmagnetic tunnel barrier layer 134, while the free layer 136 is located below the nonmagnetic tunnel barrier layer 134, and the perpendicular exchange bias layer 148 contacts a bottom surface of the free layer 136. The free layer 136 may be programmed into a first magnetization direction (e.g., an upward direction) that is parallel to the fixed vertical magnetization direction (e.g., the upward direction) of the reference layer 132, or into a second magnetization (e.g., a downward direction) that is antiparallel to the fixed vertical magnetization direction (e.g., the upward direction) of the reference layer 132.

In one embodiment, the magnetoresistive memory cell 180 comprises a magnetic polarizer layer 112 located between the first electrode 32 and the reference layer 132 and configured to stabilize the magnetization direction of the reference layer 132. The magnetic polarizer layer 112 can be any material layer or a material layer stack that can function as a hard magnetization layer, i.e., a magnetic material layer having a stable magnetization direction. In one embodiment, the magnetic polarizer layer 112 has a magnetization direction that is antiparallel to the magnetization direction of the reference layer 132, and an antiferromagnetic coupling layer 114 is located between the magnetic polarizer layer 112 and the reference layer 132 and provides antiferromagnetic coupling therebetween. In one embodiment, the magnetic polarizer layer 112 comprises a ferromagnetic multilayer structure including a superlattice, an exchange-bias-inducing antiferromagnetic layer, or a stack of at least one ferromagnetic material layer and at least one antiferromagnetic layer. Alternatively, the magnetic polarizer layer 112 comprises a hard magnetization layer (i.e., a permanent magnet).

In a non-limiting illustrative example, the magnetic polarizer layer 112 may comprise a superlattice of cobalt layers and platinum layers. The number of repetitions of a combination of a cobalt layer and a platinum layer may be in a range from 2 to 10, such as from 3 to 6, although lesser and greater number of repetitions may also be employed. In an illustrative example, the cobalt layers may have a respective thickness of 0.2 nm to 0.5 nm, and the platinum layers may have a respective thickness of about 0.1 nm to 0.5 nm. It is understood that a material layer having a thickness that is less than the thickness of a monolayer refers to a discontinuous layer having a fractional coverage that is equal to the ratio of the thickness of the material layer to the thickness of the monolayer.

The antiferromagnetic coupling layer 114 has a material composition and a thickness that provide antiferromagnetic coupling between the magnetic polarizer layer 112 and the reference layer 132. The antiferromagnetic coupling layer 114 has a thickness that induces a strong antiferromagnetic coupling between the reference layer 132 and the magnetic polarizer layer 112, such that the antiferromagnetic coupling layer 114 can “lock in” the antiparallel alignment between the magnetic polarizer layer 112 and the reference layer 132, which in turn “locks in” a particular (fixed) vertical direction of the magnetization of the reference layer 132. In one embodiment, the antiferromagnetic coupling layer can include ruthenium or iridium, and can have a thickness in a range from 0.3 nm to 1nm. The combination of the magnetic polarizer layer 112, the antiferromagnetic coupling layer 114 and the reference layer 132 may comprise a synthetic antiferromagnetic structure (SAF) 120.

The reference layer 132 includes a ferromagnetic material, such as CoFeB, CoFe, Co, Ni, NiFe, or a combination thereof. In one embodiment, the reference layer 132 is a thin CoFeB or CoFe layer having a thickness in a range from 0.5 nm to 3 nm.

The nonmagnetic tunnel barrier layer 134 can include any tunneling barrier material such as an electrically insulating material, for example magnesium oxide, aluminum oxide, or a spinel material. In one embodiment, the nonmagnetic tunnel barrier layer 134 comprises, and/or consists essentially of, magnesium oxide and has a thickness in a range from 0.5 nm to 1.5 nm, such as 0.8 nm to 1 nm.

The free layer 136 includes a ferromagnetic material, such as CoFeB, CoFe, Co, Ni, NiFe, or a combination thereof. If a CoFeB alloy is included in the free layer 136, then the atomic concentration of boron atoms within the CoFeB alloy may be in a range from 10 % to 30 % (such as 20 %), the atomic concentration of cobalt atoms within the CoFeB alloy may be in a range from 10 % to 40 % (such as 15 %), and the atomic concentration of Fe in the CoFeB layer may be in a range from 50 % to 90 % (such as 65 %). Any impurity atom in the CoFeB alloy, if present, has an atomic concentration less than 1 part per million. The thickness of the free layer 136 can be in a range from 0.5 nm to 2 nm, although lesser and greater thicknesses can also be employed.

A single monolayer of a material has an equivalent thickness of the monolayer of the material. A material that forms a fraction of a monolayer has an equivalent thickness of the fraction times the thickness of the monolayer of the material. If the fraction is less than one, then the material is a discontinuous layer in which the equivalent thickness can be less than the thickness of the monolayer of the material. As used herein, a “sub-monolayer” refers to a film having an average thickness less than one monolayer (e.g., less than 0.5 nm thick). In embodiments of the present disclosure, a sub-monolayer film can be a discontinuous layer having openings therethrough or can be a collection of individual atoms or clusters of atoms that do not form a continuous layer depending on the fractional number of an atomic layer that is present therein.

According to an embodiment of the present disclosure, a perpendicular exchange bias layer 148 is formed in contact with the free layer 136. In one embodiment, the perpendicular exchange bias layer 148 is formed directly on the free layer 136 and directly physically contacts the free layer 136 without any intervening layer in between. According to an aspect of the present disclosure, the perpendicular exchange bias layer 148 is formed on a planar surface of the free layer 136 located on an opposite side of the nonmagnetic tunnel barrier layer 134.

Generally, the perpendicular exchange bias layer 148 comprises a first set of atoms having an upward vertical magnetization direction (i.e., having a magnetization direction that is an upward vertical direction) and a second set of atoms having a downward vertical magnetization direction (i.e., having a magnetization direction that is a downward vertical direction). In one embodiment, the magnitude of the sum of all magnetic moments of the first set of atoms may be equal to, or may be substantially equal to, the magnitude of the sum of all magnetic moments of the second set of atoms. Thus, the net magnetic moment of the perpendicular exchange bias layer 148 may be zero, or may be substantially equal to zero, i.e., negligible.

In one embodiment, the first set of atoms and the second set of atoms may be provided in a same material layer. For example, the first set of atoms and the second set of atoms may be provided in a same antiferromagnetic material layer. Thus, the perpendicular exchange bias layer 148 comprises a single antiferromagnetic material layer, such as iridium manganese, platinum manganese, iron manganese or nickel manganese (i.e., alloys of manganese with Ir, Pt, Fe or Ni), or another suitable antiferromagnetic material layer, such as cobalt oxide (e.g., CoO or Co₃O₄).

In another embodiment, the first set of atoms and the second set of atoms may be provided in different material layers. For example, the first set of atoms may be provided in first-type ferromagnetic material layers and the second set of atoms may be provided in second-type ferromagnetic material layers. For example, the perpendicular exchange bias layer 148 may comprise a Co/Pt multilayer (i.e., a stack of alternating Co and Pt layers) coupled to IrMn, cobalt oxide, or another antiferromagnetic layer.

Thus, the perpendicular exchange bias layer 148 may comprise, and/or may consist essentially of, an antiferromagnetic material such as IrMn, PtMn, FeMn, NiMn, cobalt oxide or a stack thereof. The thickness of the perpendicular exchange bias layer 148 may be in a range from 1 nm to 10 nm, such as from 2 nm to 5 nm, although lesser and greater thicknesses may also be employed.

The perpendicular exchange bias layer 148 provides strong magnetic exchange bias to provide external magnetic field immunity and has a sufficiently low blocking temperature to enable switching of the unidirectional anisotropy. As used herein, a “blocking temperature” refers to the temperature below which the magnetic moments of atoms in an exchange bias system becomes “blocked” or frozen in their respective magnetization state, which provides the exchange bias effect to an adjacent ferromagnetic free layer 136. Above the blocking temperature, the thermal energy is sufficient to overcome the exchange coupling, causing the exchange bias layer to lose its ability to stabilize the magnetization direction of the adjacent ferromagnetic free layer 136.

The blocking temperature of the perpendicular exchange bias layer 148 may be controlled by various factors. For example, for a single antiferromagnetic perpendicular exchange bias layer 148, control of the layer thickness, composition (e.g., Ir to Mn ratio in IrMn), grain size and/or texture provides control of the blocking temperature. For example, decreasing the thickness and/or the grain size of an IrMn antiferromagnetic layer decreases its blocking temperature.

The magnetic properties of a Co/Pt multilayer stack coupled to an IrMn layer perpendicular exchange bias layer 148 may be controlled by controlling the ferromagnetic layer (i.e., Co layer) thickness, by whether a Pt spacer layer is located between the IrMn layer and the adjacent Co layer of the stack, the number of Pt and Co layers in the stack and the thickness of the IrMn layer.

A nonmagnetic metallic material can be provided on the side of the perpendicular exchange bias layer 148 that faces away from the free layer 136. For example, a nonmagnetic conductive capping layer 170 can be formed directly on the perpendicular exchange bias layer 148. The nonmagnetic conductive capping layer 170 includes at least one non-magnetic electrically conductive material, such as tantalum, ruthenium, tantalum nitride, copper, and/or copper nitride. For example, the nonmagnetic conductive capping layer 170 can comprise a single layer, such as a single ruthenium layer, or a layer stack including, from one side to another, a first ruthenium layer, a tantalum layer, and a second ruthenium layer. For example, the first ruthenium layer can have a thickness in a range from 0.5 nm to 1.5 nm, the tantalum layer can have a thickness in a range from 1 nm to 3 nm, and the second ruthenium layer can have a thickness in a range from 0.5 nm to 1.5 nm. Optionally, the nonmagnetic conductive capping layer 170 may include an additional non-magnetic electrically conductive material, such as W, Ti, Ta, WN, TiN, TaN, Ru, and Cu. The thickness of such an additional non-magnetic electrically conductive material can be in a range from 1 nm to 30 nm, although lesser and greater thicknesses can also be employed. The second electrode 92 can be formed over the nonmagnetic conductive capping layer 170 as a portion of a second electrically conductive line 90.

The layer stack including the SAF structure 120, the magnetic tunnel junction 140, the perpendicular exchange bias layer 148, and the nonmagnetic conductive capping layer 170 can be annealed to induce crystallographic alignment between the crystalline structure of the nonmagnetic tunnel barrier layer 134 (which may include crystalline MgO having a rock salt crystal structure) and the crystalline structure of the free layer 136.

The location of the first electrode 32 and the second electrode 92 may be switched such that the second electrode 92 is electrically connected to the SAF structure 120 and the first electrode 32 is electrically connected to the nonmagnetic conductive capping layer 170. The layer stack including the material layers from the SAF structure 120 to the nonmagnetic conductive capping layer 170 can be deposited in reverse order, i.e., from the SAF structure 120 toward the nonmagnetic conductive capping layer 170 or from the nonmagnetic conductive capping layer 170 toward the SAF structure 120. The layer stack can be formed as a stack of continuous layers, and can be subsequently patterned into discrete patterned layer stacks for each memory cell 180.

In another embodiment shown in FIG. 2B, each memory cell 180 can be electrically connected in series with a dedicated steering device 200, such an access transistor, a diode, or an ovonic threshold switch (OTS) material configured to activate a respective discrete patterned layer stack (120, 140, 148, 170) upon application of a suitable voltage to the steering device 200. The steering device may be electrically connected in series between the patterned layer stack (120, 140, 148, 170) and one of the first electrically conductive lines 30 or one of the second electrically conductive lines 90. For example, the steering device 200 is located below the SAF 120 in FIG. 2B. Alternatively, the steering device 200 may be located above the nonmagnetic conductive capping layer 170.

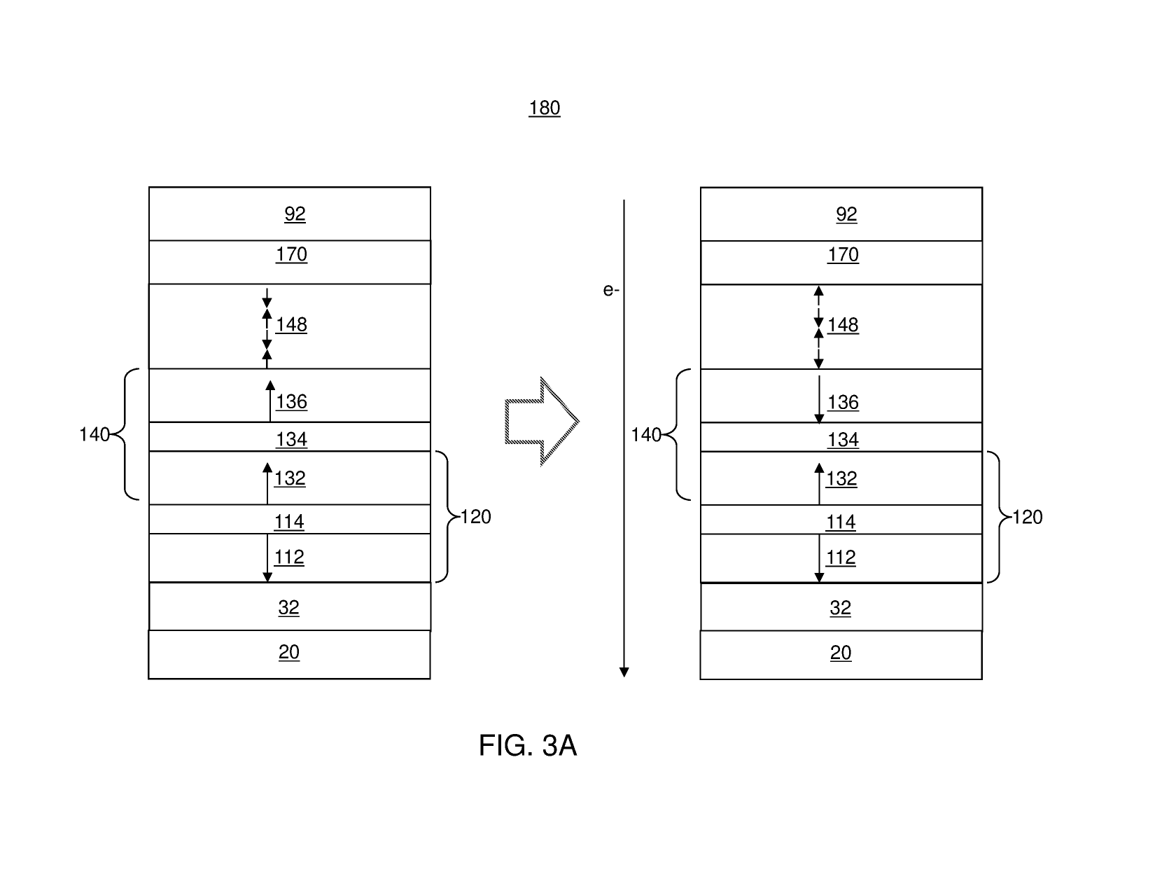

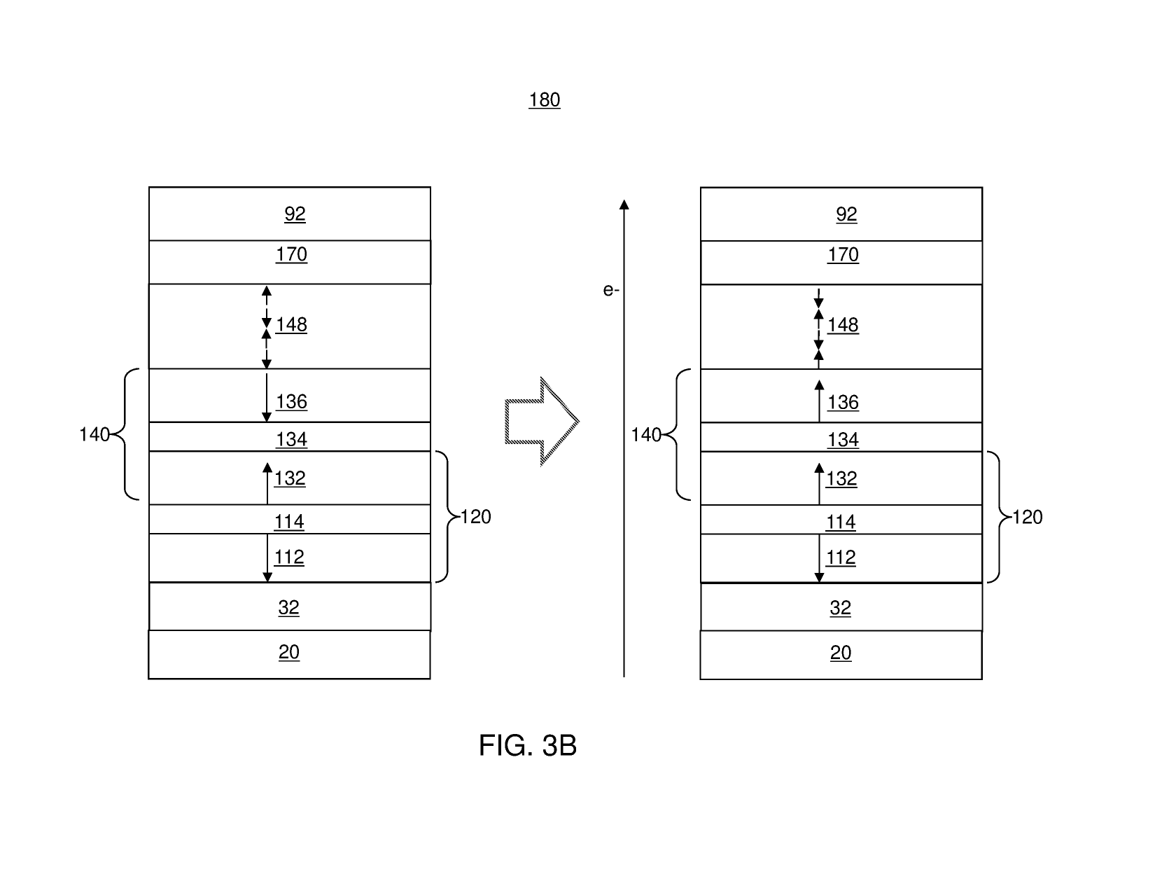

Referring to FIG. 3A, a programming method for programming the STT MRAM cell of the embodiments of the present disclosure from a parallel state to an antiparallel state is schematically illustrated. A “parallel” state of free layer 136 refers to a state of the magnetization of the free layer 136 in which the magnetization direction of the free layer 136 is parallel to the magnetization direction of the reference layer 132. An “antiparallel” state of the free layer 136 refers to a state of the magnetization of the free layer 136 in which the magnetization direction of the free layer 136 is antiparallel to the magnetization direction of the reference layer 132. In this illustrated example, the reference layer 132 has a fixed upward magnetization direction. It is understood that the STT MRAM cell 180 may also be operated in a configuration in which the fixed magnetization direction of the reference layer 132 is a downward direction.

In the illustrated configuration of FIG. 3A, the left side of the schematic illustrates the magnetoresistive memory cell 180 in the parallel state, i.e., prior to the programming operation. In other words, the magnetoresistive memory cell 180 is in the parallel state prior to performing this programming operation. The right side of the schematic illustrates the magnetoresistive memory cell 180 at the time of termination of a programming operation at which the flow of electron current “e⁻“ (of which the direction is represented by a downward arrow) is about to be terminated, and the magnetization of the free layer 136 points downward. Thus, the electron current flows from the free layer 136 to the reference layer 132 during application of a parallel-to-antiparallel programming pulse across the magnetic tunnel junction 140.

During the parallel-to-antiparallel programming operation, the spin polarization reflected from the free layer 136 in combination with self-heating effectively diminishes the exchange bias applied from the perpendicular exchange bias layer 148 to the free layer 136 so that the free layer 136 becomes easy to switch through the spin-transfer torque effect. The reflected spin polarization from the reference layer 132 switches the free layer 136 magnetization direction downward toward the reference layer 132, which provides the antiparallel alignment between the reference layer 132 and the free layer 136. When the parallel-to-antiparallel programming electron current is turned off, the interfacial magnetization of the perpendicular exchange bias layer 148 aligns along the vertical direction with the magnetization direction of the free layer 136 (i.e., downward in this example) and re-establishes the exchange bias with the free layer 136. The magnetization direction of the free layer 136 (i.e., the downward direction) can be locked along the antiparallel direction.

Referring to FIG. 3B, a programming method for programming the magnetoresistive memory cell 180 from the antiparallel state to the parallel state is schematically illustrated. The left side of the schematic illustrates the magnetoresistive memory cell 180 in the antiparallel state, i.e., prior to the programming operation. The right side of the schematic illustrates the magnetoresistive memory cell 180 at the time of termination of the programming operation at which the flow of the electron current “e⁻” (of which the direction is represented by an upward arrow) is about to be terminated, and the magnetization of the free layer 136 points upward. Thus, the electron current flows from the reference layer 132 to the free layer 136 through the magnetic tunnel junction 140 during application of the antiparallel-to-parallel programming pulse across the magnetic tunnel junction 140.

During the antiparallel-to-parallel programming operation, the spin polarization from the free layer 136 in combination with self-heating effectively diminishes the exchange bias applied from the perpendicular exchange bias layer 148 to the free layer 136 so that the free layer 136 becomes easy to switch through the spin-transfer torque effect. The spin polarization from the reference layer 132 switches the free layer 136 magnetization upward, which provides the parallel alignment between the reference layer 132 and the free layer 136. When the antiparallel-to-parallel programming electron current is turned off, the interfacial magnetization of the perpendicular exchange bias layer 148 aligns along the vertical direction with the magnetization direction of the free layer 136 (i.e. upward in this example) and re-establishes the exchange bias with the free layer 136. The magnetization direction of the free layer 136 (i.e., the upward direction) can be locked along the parallel direction.

The sensing of the magnetic state of the free layer 136 can be performed by passing a sensing current through the magnetic tunnel junction 140, and by measuring the tunneling magnetoresistance. The parallel state provides a lower magnetoresistance than the antiparallel state, and the magnetic state of the free layer 136 can be determined by a sensing circuit.

Referring to all drawings and according to various embodiments of the present disclosure, a STT magnetoresistive memory cell 180 comprises: a magnetic tunnel junction 140 comprising a reference layer 132, a free layer 136, and a nonmagnetic tunnel barrier layer 134 located between the reference layer 132 and the free layer 136; and a perpendicular exchange bias layer 148 in direct contact with a planar surface of the free layer 136.

In one embodiment, the perpendicular exchange bias layer 148 comprises an antiferromagnetic material layer. In one embodiment, the antiferromagnetic material layer has a zero net magnetization. In various embodiments, the antiferromagnetic material layer comprises IrMn, NiMn, FeMn, PtMn or cobalt oxide.

In another embodiment, the perpendicular exchange bias layer 148 comprises an antiferromagnetic material layer coupled to a stack of alternating ferromagnetic and nonmagnetic layers. In one embodiment, the stack of alternating ferromagnetic and nonmagnetic layers comprises an alternating stack of cobalt and platinum layers, and the antiferromagnetic material layer comprises IrMn or cobalt oxide.

In one embodiment, the STT magnetoresistive memory cell of Claim 1, further comprises a magnetic polarizer layer 112 magnetically coupled with the reference layer 132 and configured to fix a direction of a magnetization of the reference layer 132; and an antiferromagnetic coupling layer 114 located between the polarizer layer 112 and the reference layer 132.

In one embodiment, the STT magnetoresistive memory cell of Claim 1, further comprises a nonmagnetic conductive capping layer 170, wherein the perpendicular exchange bias layer 148 is located between the free layer 136 and the nonmagnetic conductive capping layer 170.

In one embodiment, the STT magnetoresistive memory cell comprises a two terminal memory cell in electrical contact with a bit line 90 and a word line 30.

In one embodiment, the free layer 136 comprises CoFeB or CoFe, the reference layer 132 comprises CoFeB or CoFe, and the nonmagnetic tunnel barrier layer 134 comprises MgO.

In one embodiment, selector element 200 is electrically connected in series with the magnetic tunnel junction 140.

In one embodiment, the reference layer 132 is located above the substrate 20, the free layer 136 is located above the reference layer 132, and the perpendicular exchange bias layer is located above and in contact with a top surface of the free layer 136.

In another embodiment, the free layer 136 is located above the substrate 20, the reference layer 132 is located above the free layer 136, and the perpendicular exchange bias layer is located below and in contact with a bottom surface of the free layer.

In one embodiment, a method of operating the STT magnetoresistive memory cell comprises flowing an electron current in a first direction from the free layer 136 to the reference layer 132 to switch the STT magnetoresistive memory cell 180 from a parallel state to an antiparallel state; and flowing the electron current in a second direction from the reference layer 132 to the free layer 136 to switch the STT magnetoresistive memory cell 180 from the antiparallel state to the parallel state.

In one embodiment, the method also includes applying an external magnetic field to the STT magnetoresistive memory cell 180 in either the parallel state or the antiparallel state, wherein the STT magnetoresistive memory cell 180 returns to the respective parallel state or the antiparallel state after the application of the external magnetic field is stopped (e.g., after the external magnetic field is turned off or the MRAM device 500 is removed from the external magnetic field).

The perpendicular exchange bias layer 148 causes the free layer 136 to be immune or less sensitive to external magnetic fields (i.e., the magnetization direction of the free layer 136 returns to its original direction after the external magnetic field is turned off). This improves the reliability and the data retention of the magnetoresistive memory cell 180 of the embodiments of the present disclosure.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A spin transfer torque (STT) magnetoresistive memory cell, comprising:
a magnetic tunnel junction comprising a reference layer, a free layer, and a nonmagnetic tunnel barrier layer located between the reference layer and the free layer; and
a perpendicular exchange bias layer in direct contact with a planar surface of the free layer.

2. The STT magnetoresistive memory cell of claim 1, wherein the perpendicular exchange bias layer comprises an antiferromagnetic material layer.

3. The STT magnetoresistive memory cell of claim 2, wherein the antiferromagnetic material layer has a zero net magnetization.

4. The STT magnetoresistive memory cell of claim 2, wherein the antiferromagnetic material layer comprises IrMn.

5. The STT magnetoresistive memory cell of claim 2, wherein the antiferromagnetic material layer comprises NiMn.

6. The STT magnetoresistive memory cell of claim 2, wherein the antiferromagnetic material layer comprises FeMn.

7. The STT magnetoresistive memory cell of claim 2, wherein the antiferromagnetic material layer comprises PtMn.

8. The STT magnetoresistive memory cell of claim 2, wherein the antiferromagnetic material layer comprises cobalt oxide.

9. The STT magnetoresistive memory cell of claim 1, wherein the perpendicular exchange bias layer comprises an antiferromagnetic material layer coupled to a stack of alternating ferromagnetic and nonmagnetic layers.

10. The STT magnetoresistive memory cell of claim 9, wherein stack of alternating ferromagnetic and nonmagnetic layers comprises an alternating stack of cobalt and platinum layers.

11. The STT magnetoresistive memory cell of claim 10, wherein the antiferromagnetic material layer comprises IrMn or cobalt oxide.

12. The STT magnetoresistive memory cell of claim 1, further comprising:
a magnetic polarizer layer magnetically coupled with the reference layer and configured to fix a direction of a magnetization of the reference layer; and
an antiferromagnetic coupling layer located between the polarizer layer and the reference layer.

13. The STT magnetoresistive memory cell of claim 1, further comprising a nonmagnetic conductive capping layer, wherein the perpendicular exchange bias layer is located between the free layer and the nonmagnetic conductive capping layer.

14. The STT magnetoresistive memory cell of claim 1, wherein the STT magnetoresistive memory cell comprises a two terminal memory cell in electrical contact with a bit line and a word line.

15. The STT magnetoresistive memory cell of claim 1, wherein the free layer comprises CoFeB or CoFe, the reference layer comprises CoFeB or CoFe, and the nonmagnetic tunnel barrier layer comprises MgO.

16. The STT magnetoresistive memory cell of claim 1, further comprising a selector element electrically connected in series with the magnetic tunnel junction.

17. The STT magnetoresistive memory cell of claim 1, further comprising a substrate, wherein the reference layer is located above the substrate, the free layer is located above the reference layer, the perpendicular exchange bias layer is located above the free layer, and the planar surface of the free layer comprises the top surface of the free layer.

18. The STT magnetoresistive memory cell of claim 1, further comprising a substrate, wherein the free layer is located above the substrate, the reference layer is located above the free layer, the perpendicular exchange bias layer is located below the free layer, and the planar surface of the free layer comprises the bottom surface of the free layer.

19. A method of operating the STT magnetoresistive memory cell of claim 1, comprising:
flowing an electron current in a first direction from the free layer to the reference layer to switch the STT magnetoresistive memory cell from a parallel state to an antiparallel state; and
flowing the electron current in a second direction from the reference layer to the free layer to switch the STT magnetoresistive memory cell from the antiparallel state to the parallel state.

20. The method of claim 19, further comprising applying an external magnetic field to the STT magnetoresistive memory cell in either the parallel state or the antiparallel state, wherein the STT magnetoresistive memory cell returns to the respective parallel state or the antiparallel state after the application of the external magnetic field is stopped.
